(19) United States
(12) Patent Application Publication
(10) Pub. No.: US 2023/0055603 A1
(43) Pub. Date: Feb. 23, 2023

(54) ENHANCED PATTERNING PROCESS FOR QUBIT FABRICATION

(71) Applicant: International Business Machines Corporation, Armonk, NY (US)

(72) Inventor: Gerald W. Gibson, Danbury, CT (US)

(21) Appl. No.: 17/445,251

(22) Filed: Aug. 17, 2021

(51) Int. Cl. H01L 29/88; H01L 29/66

(52) U.S. Cl. CPC H01L 29/88; H01L 29/66151

(57) ABSTRACT

The method that includes cleaning the surface of a silicon wafer, forming a sacrificial layer on top of the silicon wafer; forming at least one window in the sacrificial layer exposing the surface of the silicon wafer, and processing the silicon wafer, wherein the processing includes forming at least one layer in the at least window, such that, wherein the at least one layer includes a first section that is direct contact with the silicon wafer and the walls of the at least one window created by the sacrificial layer, a main section that extends from the first section, and a bump out section that extends from the sides of the main section and the bottom surface of the bump out section is in contact with the sacrificial layer. Prior to the insertion into a dilute refrigeration unit removing the sacrificial layer by exposing it to a solvent, wherein the removal of the sacrificial layer causes the bottom surface of the bump section, the side portion of the first section, and the top surface of the silicon form a space without material.

### STATEMENT REGARDING FEDERALLY FUNDED RESEARCH AND DEVELOPMENT

This invention was made with U.S. Government support. The U.S. Government has certain rights in this invention.

### BACKGROUND

The present invention relates generally to a field of chip manufacturing, and more particularly to a protective layer to prevent defects from forming.

Silicon wafers are commonly used during the manufacturing of qubits. A problem of the cleanliness of the surfaces on the wafer has given arise to multiple problems. Efforts to date have largely addressed a cleaning of exposed surfaces at various points during the qubit fabrication sequence. Multiple cleaning steps are time consuming and can lead to over-etching, unwanted side-products of chemical reactions, and/or residual chemical compounds.

### BRIEF SUMMARY

Additional aspects and/or advantages will be set forth in part in the description which follows and, in part, will be apparent from the description, or may be learned by practice of the invention.

The silicon wafer that includes at least one layer located directly on the top of the silicon wafer, wherein the at least one layer includes a first section that is direct contact with the silicon wafer, a main section above the first section, and a bump out section that extends from the sides of the main section, wherein bottom surface of the bump section, a side portion of the first section, and the top surface of the silicon form a space without material.

The method that includes cleaning the surface of a silicon wafer, forming a sacrificial layer on top of the silicon wafer; forming at least one window in the sacrificial layer exposing the surface of the silicon wafer, and processing the silicon wafer, wherein the processing includes forming at least one layer in the at least window, such that, wherein the at least one layer includes a first section that is direct contact with the silicon wafer and the walls of the at least one window created by the sacrificial layer, a main section that extends from the first section, and a bump out section that extends from the sides of the main section and the bottom surface of the bump out section is in contact with the sacrificial layer. Prior to the insertion into a dilute refrigeration unit removing the sacrificial layer by exposing it to a solvent, wherein the removal of the sacrificial layer causes the bottom surface of the bump section, the side portion of the first section, and the top surface of the silicon form a space without material.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a cross section of a substrate during fabrication stages, in accordance with an embodiment of the present invention.

FIG. 2 illustrates a cross section of a substrate during fabrication stages, in accordance with an embodiment of the present invention.

FIG. 3 illustrates a cross section of a substrate during fabrication stages, in accordance with an embodiment of the present invention.

FIG. 4 illustrates a cross section of a substrate during fabrication stages, in accordance with an embodiment of the present invention.

FIG. 5 illustrates a cross section of a substrate during fabrication stages, in accordance with an embodiment of the present invention.

FIG. 6 illustrates a cross section of a substrate during fabrication stages, in accordance with an embodiment of the present invention.

FIG. 7 is a flowchart depicting a method of fabrication, in accordance with an embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” can be understood to include any integer number greater than or equal to one, i.e. one, two, three, four, etc. The terms “a plurality” can be understood to include any integer number greater than or equal to two, i.e. two, three, four, five, etc. The term “connection” can include both an indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. The terms “about” or “substantially” are intended to include the degree of error associated with measurement of the particular quantity based upon the equipment available at the time of filing application. For example, “about” can include a range of ±8% or 5%, or 2% of a given value. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value. The terms “about” or “substantially” are intended to include the degree of error associated with measurement of the particular quantity based upon the equipment available at the time of filing application.

Various processes used to form a microelectronic structure fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage.

Reference will now be made in detail to the embodiments of the present invention, examples of which are illustrated in the accompanying drawings, wherein like reference numerals refer to like elements throughout. Embodiments of the invention are generally directed to a method of maintaining substrate cleanliness whereby the pristine substrate is covered by a protective layer which is only removed immediately prior to insertion of the fabricated devices into the dilution refrigerator, thus protecting the substrate from exposure to both process environments and ambient during the fabrication sequence. Prior to qubit fabrication, the silicon substrate is carefully cleaned and passivated, then a sacrificial layer of thermal silicon dioxide, or other appropriate material such as titanium it is formed on the silicon wafer to create a high quality, buried, oxide-silicon interface.

The silicon dioxide layer can be etched to form windows having lateral dimensions slightly smaller than subsequent layers. The layer can be, for example, a metal or trilayer stack, and can be deposited/formed and qubits, metal wiring, or other electrical components can be formed from these layers. Following formation, and just prior to placing a chip into the dilution refrigerator, the sacrificial silicon dioxide layer covering the silicon substrate is removed in hydrofluoric acid to expose the silicon substrate and terminate its surface with hydrogen bonds, thus passivating it. The acid will undercut, and fully remove, the silicon dioxide layer which is partially covered by the base electrode metal. The net result of this approach is that a nearly pristine, and passivated, substrate surface is placed into the dilution refrigerator, where it is subsequently held under high vacuum (i.e., an inert environment). The passivated surface the silicon wafer prevents the formation of oxides or other compounds that might cause an interference, thus improving the electrical qualities of the electrical components formed on the passivate substrate.

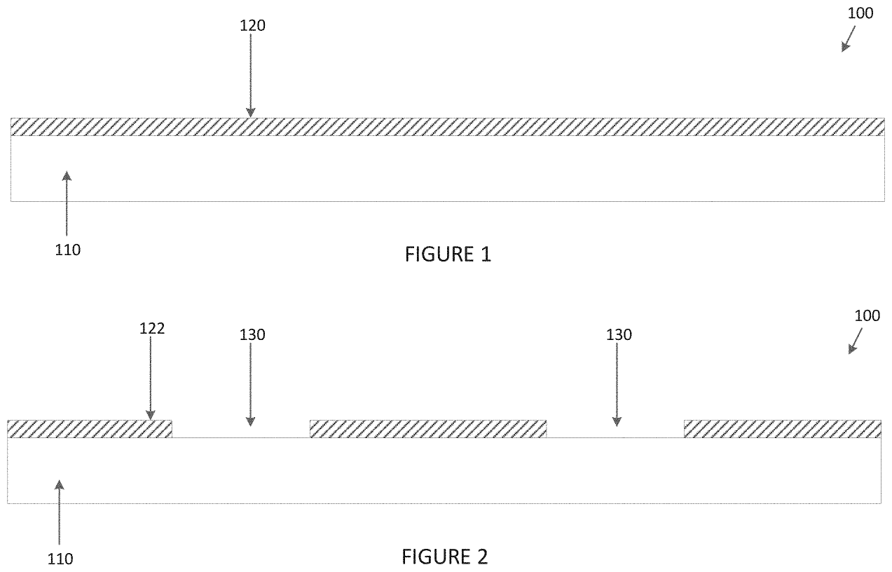

FIGS. 1 and 2 illustrate a cross section of a substrate during fabrication stages, in accordance with an embodiment of the present invention.

FIG. 1 illustrate a product 100 during the initial stages of fabrication. The product 100 is formed from a substrate 110, for example, a silicon wafer, a SiGe wafer, a II-IV material, a III-V material, or any type of suitable material to act as a substrate for fabrication of chips. The silicon wafer 110 is cleaned and passivated at the start of the fabrication process. The sacrificial layer 120, for example, silicon dioxide or titanium, is formed on top of the silicon wafer 110, by one of the method described below. The sacrificial layer 120 can be formed utilizing different deposition techniques, for example, PVD, CVD, ALD or another deposition technique can be utilized in the formation of the sacrificial layer 120.

FIG. 2 illustrates a product 100 during the initial stages of fabrication. A desired pattern/mask is laid out on the sacrificial layer 120 for the creation of window/holes in etched sacrificial layer 122. Windows/holes 130 are formed/etched in the etched sacrificial layer 122 to have a lateral dimensions a less than the layer to that will fill the window/holes 130. The lateral dimension is such that the layer will fill the window/hole 130 and the layer will extend a distance across the top surface of the etched sacrificial layer 122. An etched sacrificial layer 122 can be formed utilizing different etching techniques, for example, wet/dry etching, CMP, or another etching technique that can be utilized in the formation of the windows/holes 130 in the etch sacrificial layer 122.

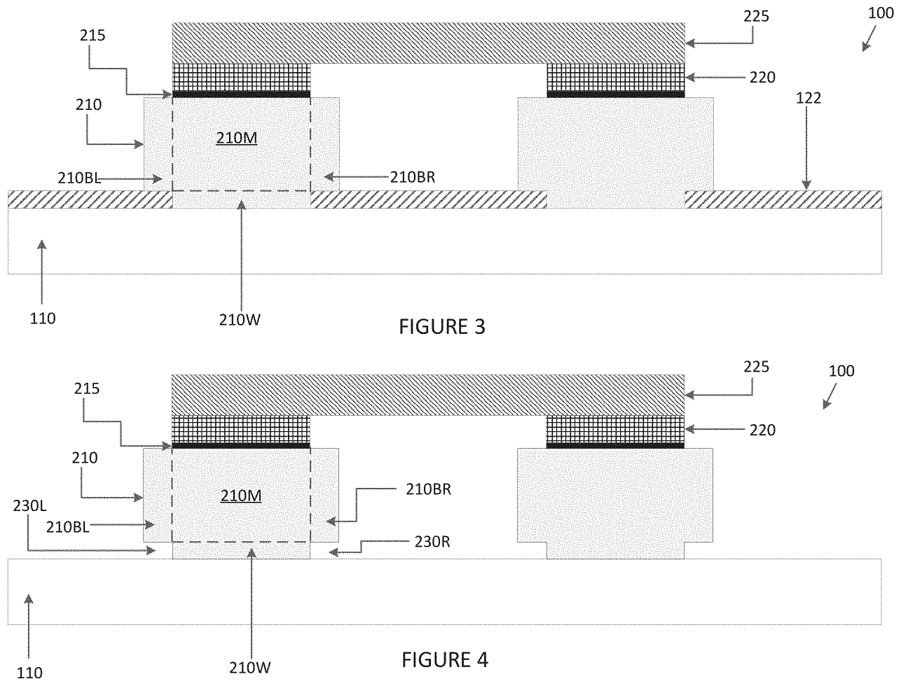

FIGS. 3 and 4 illustrate a cross section of a substrate during fabrication stages, in accordance with an embodiment of the present invention.

FIG. 3 illustrates a cross section at the later stages of fabrication of the product 100. For example, the base electrode 210, is formed within the windows/holes 130 of the sacrificial layer 120. The dashed lines in FIG. 3 illustrate approximate boundaries between different sections of the base electrode 210. The base electrode 210 has a first section 210W that fills the window/holes 130 in the etched sacrificial layer 122. The base section 210W is in direct contact with the silicon wafer 210W and in direct contact with the etched sacrificial layer 122 that makes the walls of the windows/holes 130. The base electrode 210 has a main body 210M that extends above the first section 210W. The base electrode 210 has a first bump out section 210BL extending out from the main body 210M above a section of the etched sacrificial layer 122. The base electrode 210 has a second bump section 210BR extending out from the main body 210M above a section of the etched sacrificial layer 122. The base electrode 210 can be formed utilizing different deposition techniques, for example, PVD, CVD, ALD or another deposition technique can be utilized in the formation of the base electrode 210. The formation of the base electrode 210 is for example purposes only and any type of layer can be formed. The base electrode can be comprised of, for example, Niobium.

The electrical component can be formed on top of the base electrode 210. For example, the electrical component can include a tunnel barrier 215, a counter electrode 220, and a connecting layer 225. The tunnel barrier 215 and counter electrode 220 may be formed above the base electrode 210, while connecting layer 225 forms a bridge between a first structure including the base electrode 210, the tunnel barrier 215, a counter electrode 220, and a second structure containing the base electrode 210, the tunnel barrier 215, a counter electrode 220. The tunnel barrier 140 can be, for example, Al/Aluminum Oxide, the counter electrode 150 can be, for example, Niobium, and the connecting layer 180 can be, for example, Aluminum or Niobium. The previously listed materials are meant to for example purposes only and should not be limiting the scope of the invention.

FIG. 4 illustrates the product 100 following the removal of the etched sacrificial layer 122, and prior to the product 100 being entered into a dilute refrigeration unit (not shown). The etched sacrificial layer 122 is removed immediately prior to the product 100 being inserted into a dilute refrigeration unit to prevent the formation of unwanted oxide or other materials in the location of the removed etched sacrificial layer 122. The product 100 is exposed to a solvent, for example, hydrofluoric acid, to remove the etched sacrificial layer 122, for example, silicon dioxide layer, covering the silicon wafer 110. The silicon wafer 110 is exposed by the removal of the etched sacrificial layer 122 and the removal process of the etched sacrificial layer 122 terminates the exposed silicon on the surface silicon wafer 110 with hydrogen bonds, thus passivating the surface of the silicon wafer. The solvent selectively removes all of the etched sacrificial layer 122, with respect to the base electrode 210, resulting in an undercut gap 230 of the base electrode 210. The dashed lines in FIG. 4 illustrate approximate boundaries between the different sections of the base electrode 210. The base electrode 210 has a first section 210W that is in direct contact with the silicon wafer 110. The base electrode 210 has a main body 210M that extends above the first section 210W. The base electrode 210 has a first bump out section 210BL extending out from the main body 210M above the silicon wafer 110, wherein undercut gap 230L is located beneath the bottom surface of the first bump out section 210BL. The undercut gap 230L is defined by the top surface of the silicon wafer 110, the side section of the first section 210W and the bottom surface of the first bump section 210BL, without material between the surfaces.

The base electrode 210 has a second bump section 210BR extending out from the main body 210M above a section of the silicon wafer 110, wherein undercut gap 230R is located beneath the bottom surface of the second bump out section 210BR. The undercut gap 230R is defined by the top surface of the silicon wafer 110, the side section of the first section 210W and the bottom surface of the second bump section 210BR, without material between the surfaces. A net result of this approach is that a nearly pristine, and passivated, substrate surface is placed into the dilution refrigerator, where it is subsequently held under high vacuum. By passivating the surface of the silicon wafer near the time of insertion into the dilution refrigerator, oxides or other compounds that might cause interference can be limited from the final product introduced to the dilution refrigerator, thus improving the electrical qualities of the electrical components formed on the passivate substrate.

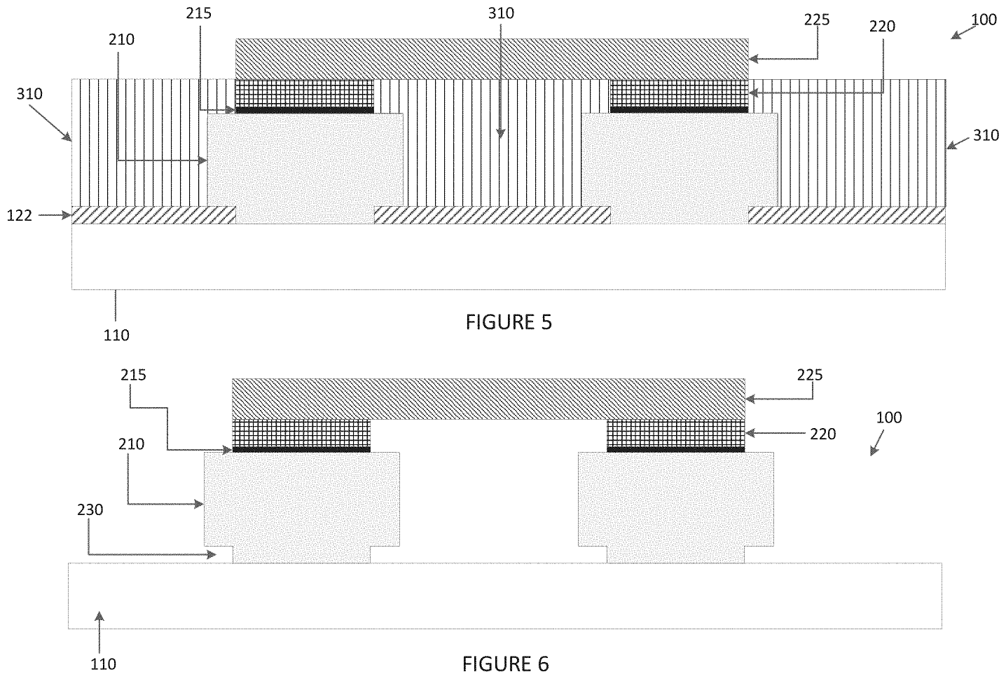

FIGS. 5 and 6 illustrate a cross sectional view of a substrate during alternative fabrication stages, in accordance with an embodiment of the present invention.

FIG. 5 illustrates the later stages of the alternative fabrication of the product 100 that is similar to the product 100 described above. During the fabrication stages, a second sacrificial layer 310 is formed on top of the etched sacrificial layer 122. The second sacrificial layer 310 can be formed utilizing different deposition techniques, for example, PVD, CVD, ALD or another deposition technique can be utilized in the formation of the second sacrificial layer 310. The second sacrificial layer 310 can be the same material as the sacrificial layer 120 or it it can be a different material as long as the material is easy to remove without damaging the electronic component

The second sacrificial layer 310 is formed on top of the sacrificial layer 120. Furthermore, the second sacrificial layer 310 can be added to cover additional surfaces of the structure 100, and prevent unwanted chemical reactions (e.g., oxidation) on those surfaces. For example, the second sacrificial layer 310 can cover exposed areas of the tunnel barrier 215, the counter electrode 200 and the connecting layer 225. The second sacrificial layer 310 acts as a barrier to prevent the formation of side-products of chemical reactions, oxides, and/or residual chemical compounds on the exposed surface of the electronic component.

FIG. 6 illustrates the stage of the product 100 immediately prior to being entered into the dilute refrigeration unit (not shown) after the first sacrificial layer 120 and the second sacrificial layer 310 is removed. The product 100 as illustrated by FIG. 6 is the same product 100 as illustrate by FIG. 4 above.

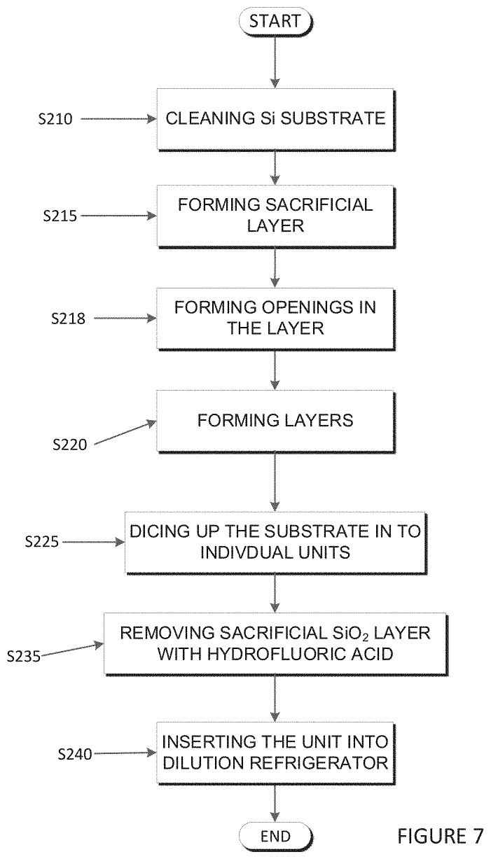

FIG. 7 is a flowchart depicting a method of fabrication, in accordance with an embodiment of the present invention.

A silicon wafer 110 is cleaned and passivated at the start of the manufacturing process (S210). A sacrificial layer 120 is formed on the surface of the silicon wafer 110 (S215). The sacrificial layer 120 acts as a barrier prevent the formation of unwanted layers, defects, or other issues on the surface of the silicon wafer 110. A desired pattern/mask is laid out on the sacrificial layer 120 for the creation of window/holes in the sacrificial layer 120. Windows/holes 130 are formed/etched in the sacrificial layer 120 to have a lateral dimensions a less than the layer to that will fill the window/holes 130 (S215). The lateral dimension is such that the layer will fill the window/hole 130 and the layer will extend a distance across the top surface of the etched sacrificial layer 122. The etched sacrificial layer 122 can be formed utilizing different etching techniques, for example, wet/dry etching, CMP, or another etching technique that can be utilized in the formation of the windows/holes 130 in the etch sacrificial layer 122.

The at least one layer, for example, the base electrode 210, is formed to fill the window/holes 130 to, such that, the at least one layer extends a distance across the top surface of the etched sacrificial layer 122 (S220). The base electrode 210 has a first section 210W that fills the window/holes 130 in the etched sacrificial layer 122. The base section 210W is in direct contact with the silicon wafer 210W and in direct contact with the etched sacrificial layer 122 that makes the walls of the windows/holes 130. The base electrode 210 has a main body 210M that extends above the first section 210W. The base electrode 210 has a first bump out section 210BL extending out from the main body 210M above a section of the etched sacrificial layer 122. The base electrode 210 has a second bump section 210BR extending out from the main body 210M above a section of the etched sacrificial layer 122. The base electrode 210 can be formed utilizing different deposition techniques, for example, PVD, CVD, ALD or another deposition technique can be utilized in the formation of the base electrode 210. During the fabrication process of the at base electrode 210 or an electronic component comprised of a plurality of other layers 215, 220, 225, or an optional second sacrificial layer 310 can be formed on the base electrode 210 or on the etched sacrificial layer 122 (S220). The second sacrificial layer 310 can be the same material as the sacrificial layer 120 or it can be a different material as long as the material is easy to remove without damaging the electronic component.

Multiple products 100 are formed at a same time on the silicon wafer 110, so once the silicon wafer 110 has finished with the manufacturing process then the silicon wafer 110 is diced into individual products 100 that will be placed within a dilution refrigeration (S225). Immediately prior to the product 100 insertion into a dilute refrigeration unit, the product 110 is exposed a solvent, for example, hydrofluoric acid, to fully remove the etched sacrificial layer 120 (S235). Once all of the sacrificial layer 120 is removed then the undercut gap 230 is exposed (S235). The silicon wafer 110 is exposed by the removal of the etched sacrificial layer 122 and the removal process of the etched sacrificial layer 122 terminates the exposed silicon on the surface silicon wafer 110 with hydrogen bonds, thus passivating the surface of the silicon wafer. The solvent selectively removes all of the etched sacrificial layer 122, with respect to the base electrode 210, resulting in an undercut gap 230 of the base electrode 210. The dashed lines in FIG. 4 illustrate approximate boundaries between the different sections of the base electrode 210. The base electrode 210 has a first section 210W that is in direct contact with the silicon wafer 110. The base electrode 210 has a main body 210M that extends above the first section 210W. The base electrode 210 has a first bump out section 210BL extending out from the main body 210M above the silicon wafer 110, wherein undercut gap 230L is located beneath the bottom surface of the first bump out section 210BL. The undercut gap 230L is defined by the top surface of the silicon wafer 110, the side section of the first section 210W and the bottom surface of the first bump section 210BL, without material between the surfaces.

The base electrode 210 has a second bump section 210BR extending out from the main body 210M above a section of the silicon wafer 110, wherein undercut gap 230R is located beneath the bottom surface of the second bump out section 210BR. An undercut gap 230R is defined by the top surface of the silicon wafer 110, the side section of the first section 210W and the bottom surface of the second bump section 210BR, without material between the surfaces. The etched sacrificial layer 122 that is removed from the surface of the silicon wafer 110 will passivate the surface of the silicon wafer 110 (S235). The hydrofluoric acid to expose the silicon wafer 110 and terminate its surface with hydrogen bonds, thus passivating it. Once the sacrificial layer 120 is removed then the product 100 is inserted into the dilute refrigeration unit (S240).

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. An apparatus comprising:
a silicon wafer; and
at least one layer located directly on the top of the silicon wafer, wherein the at least one layer includes a first section that is direct contact with the silicon wafer, a main section above the first section, and a bump out section that extends from the sides of the main section, wherein bottom surface of the bump section, a side portion of the first section, and the top surface of the silicon form a space lacking material.

2. The apparatus of claim 1, further comprising:
at least one electrical component located on top of the at least one layer.

3. The apparatus of claim 2, wherein the at least one electrical component is formed from one additional layer.

4. The apparatus of claim 3 wherein the at least one electrical component is formed from a plurality of different layers.

5. A method comprising:
cleaning a surface of a silicon wafer;
forming a sacrificial layer on top of the silicon wafer;
forming at least one window in the sacrificial layer exposing the surface of the silicon wafer within the window,
processing the silicon wafer, wherein the processing includes forming at least one layer in the at least window, such that, wherein the at least one layer includes a first section that is direct contact with the silicon wafer and the walls of the at least one window created by the sacrificial layer, a main section that extends from the first section, and a bump out section that extends from the sides of the main section and the bottom surface of the bump out section is in contact with the sacrificial layer;
prior to the insertion into a dilute refrigeration unit removing the sacrificial layer by exposing it to a solvent, wherein the removal of the sacrificial layer causes the bottom surface of the bump section, the side portion of the first section, and the top surface of the silicon form a space without material.

6. The method of claim 5, wherein the sacrificial layer is selected from silicon dioxide or titanium.

7. The method of claim 6, wherein the solvent includes hydrofluoric acid.

8. The method of claim 5, further comprising:
forming a passivated surface of silicon located at the area on the silicon wafer where the sacrificial layer was eliminated.

9. The method of claim 5, further comprising:
forming at least one electrical component on the at least one layer.

10. The method of claim 9, wherein the at least one electrical component is formed from one additional layer.

11. The method of claim 9, wherein the at least one electrical component is formed from a plurality of different layers.

12. The method of claim 5, further comprising:
during the processing steps of the silicon wafer forming a second sacrificial layer on the exposed surfaces of the sacrificial layer and the at least one layer.

13. The method of claim 12, wherein the second sacrificial layer and the sacrificial layer are comprised of a same material.

14. The method of claim 12, wherein said second sacrificial layer and the sacrificial layer are comprised of different materials.

15. An apparatus comprising:
a first sacrificial layer located on a first portion of a substrate;
a first base electrode, wherein said first base electrode includes a first section that is direct contact with the silicon wafer, a main section above the first section, and a bump out section that extends from the sides of the main section, wherein bottom surface of the bump section, a side portion of the first section, and the top surface of the silicon form a space without material;
a first tunnel barrier located the top of the first base electrode;
a second base electrode, wherein the second base electrode includes a first section that is direct contact with the silicon wafer, a main section above the first section, and a bump out section that extends from the sides of the main section, wherein bottom surface of the bump section, a side portion of the first section, and the top surface of the silicon form a space without material; and
a second tunnel barrier located the top of the second base electrode;
a connecting layer electrically connecting the first tunnel barrier to the second tunnel barrier.

16. The apparatus of claim 15, wherein a material of said sacrificial layer comprises a material selected from a group consisting of: silicon dioxide and titanium.

17. The apparatus of claim 15, further comprising:
a passivated surface of silicon located on the portion of the top surface of said silicon wafer.
